(19) United States
(12) Patent Application Publication
(10) Pub. No.: US 2012/0098090 A1
(43) Pub. Date: Apr. 26, 2012

(54) HIGH-EFFICIENCY POWER CONVERTERS WITH INTEGRATED CAPACITORS

(75) Inventors: Francois Hebert, San Mateo, CA (US); Shea Petricek, Dallas, TX (US); Nikhil Kelkar, Saratoga, CA (US)

(73) Assignee: INTERSIL AMERICAS INC., Milpitas, CA (US)

(21) Appl. No.: 13/069,789

(22) Filed: Mar. 23, 2011

Related U.S. Application Data
(60) Provisional application No. 61/405,931, filed on Oct. 22, 2010.
(60) Provisional application No. 61/421,280, filed on Dec. 9, 2010.

(51) Int. Cl. H01L 29/92; H01L 21/56

(52) U.S. Cl. 257/532; 438/107; 257/E21.499; 257/E29.342

(57) ABSTRACT

A power converter device comprises a substrate, a power die mounted on the substrate, and a capacitor die mounted over the power die in a stacked configuration. The capacitor die is electrically coupled to the power die. A packaging material encapsulates the power die and the capacitor die. An integrated circuit die can also be mounted to the substrate and electrically coupled to the power die to receive power signals from the power die, with the packaging material also encapsulating the integrated circuit die.

This application claims the benefit of priority to U.S. Provisional Application No. 61/421,280, filed on Dec. 9, 2010, and to U.S. Provisional Application No. 61/405,931, filed on Oct. 22, 2010, the disclosures of which are incorporated by reference.

### DRAWINGS

Understanding that the drawings depict only exemplary embodiments and are not therefore to be considered limiting in scope, the exemplary embodiments will be described with additional specificity and detail through the use of the accompanying drawings, in which:

FIGS. 1A and 1B are a plan view and a side view in section of a power converter according to one embodiment;

FIG. 2 is a plan view of a power die according to one embodiment that can be implemented in a power converter;

FIG. 3 is a side view of a capacitor according to one embodiment that can be implemented in a power converter;

FIGS. 4A and 4B are a plan view and a side view in section of a power converter according to another embodiment;

FIGS. 5A and 5B are a plan view and a side view in section of a power converter according to a further embodiment;

FIGS. 6A and 6B are a plan view and a side view in section of a power converter according to an additional embodiment;

FIGS. 7A and 7B are a plan view and a side view in section of a power converter according to another embodiment;

FIGS. 8A and 8B are a plan view and a side view in section of a power converter according to an additional embodiment;

FIG. 9 is a block diagram of an electronic system that includes a power converter with one or more integrated capacitors; and

FIGS. 10A-10C are graphical plots showing the results of computer simulations to evaluate the impact of an integrated capacitor on circuit performance.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. It is to be understood that other embodiments may be utilized and that mechanical and electrical changes may be made. The following detailed description is, therefore, not to be taken in a limiting sense.

High-efficiency power converters with integrated capacitors are disclosed herein. The present power converters utilize a chip capacitor having an integrated circuit compatible planar structure that is thin and compatible with standard package outlines. The chip capacitor is stacked over a single power die. The power die includes highs side and low side power devices that are monolithically integrated in a single die, with the phase (switched output) node at the bottom of the die. The top of the high-side device is the voltage input (Vin) and the top of the low-side device is ground.

The chip capacitor is mounted over the top of the power die in a stacked configuration prior to packaging. In some embodiments, the capacitor can be mounted by flip-chip bonding to the power die, or by flip-chip bonding on a metal plate that is coupled to the power die. In other embodiments, the capacitor is mounted to the power die by wire bonding. The components of the power converter are encapsulated in a molding package material such that the capacitor does not extend outside of the molded package.

The capacitor can be implemented with a capacitance value selected to minimize power loss of the power converter. In the present approach, the distance between a critical node and the capacitor is reduced, resulting in a parasitic inductance reduced to an acceptable level between the capacitor electrodes and the voltage input (Vin) and ground nodes. The present approach is particularly suitable for direct current (DC)-to-DC synchronous power converters.

The present power converters, which can have one or more integrated capacitors, can be optionally combined in a package with an integrated circuit (IC) to produce a “stand alone” power converter or regulator product. The IC can be a full featured switching modulator and converter, which generates a pulse-width modulation (PWM) signal, drives the gates of the metal oxide semiconductor field effect transistors (MOSFETs) in the power die, has over current and over voltage protection, and the like. The IC die can also be a gate driver, which takes a single PWM signal and drives the gates of the MOSFETs in the power die, a switching regulator circuit, or the like.

In the embodiments described as follows, the power converters with integrated capacitors include a power die, and an IC die that is optional. Thus, the various embodiments of the power converter described hereafter with reference to the drawings can be implemented with or without the IC die as desired.

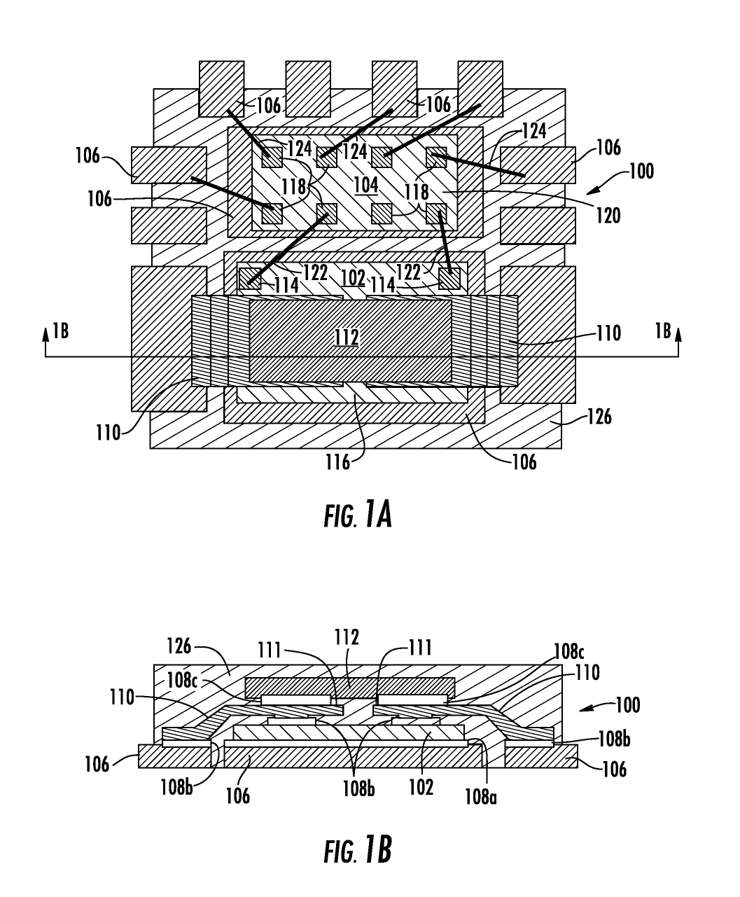

FIGS. 1A and 1B illustrate a power converter 100 according to one embodiment. The power converter 100 includes a power die 102 and an optional IC die 104 that are mounted to a substrate, which can include inner portions of a metal lead frame 106. The power die 102 and IC die 104 can be mounted with one or more conductive die attach pads 108a, which can be formed form a eutectic solder bond, a conductive adhesive material, or the like.

A pair of metal plates 110 is coupled to power die 102 and outer portions of lead frame 106 with conductive die attach pads 108b. The metal plates 110 each include a raised portion 111 that is coupled to power die 102, and provide one or more conductive paths between power die 102 and lead frame 106. The metal plates 110 can be made of copper, copper alloys, multi-layer structures such as Cu/Mo/Cu, and the like.

A capacitor die 112 is mounted on metal plates 110 by flip-chip bonding such as with a conductive die attach pads 108c. The capacitor die 112 is attached to each raised portion 111 of metal plates 110 over power die 102.

A plurality of bond pads 114 are located on an upper surface 116 of power die 102. A plurality of bond pads 118 are located on an upper surface 120 of IC die 104. The bond pads 114 are electrically connected to respective bond pads 118 by bond wires 122, which provide power signals from power die 102 to IC die 104. Other bond pads 118 are electrically connected to various outer portions of lead frame 106 by bond wires 124 to provide outside connections for IC die 104.

A packaging material 126, such as a polymer molding compound, encapsulates the various components of power converter 100, including power die 102, IC die 104, and capacitor die 112, to seal the components from environmental contamination. Exemplary packaging materials include molding compounds formed of various resins including aromatic or multi-aromatic resins, phenolic resins, and the like, which can include a filler material such as silica or other materials. For example, improved electro magnetic interference (EMI) shielding can be obtained by adding ferrite powder as a filler material to the resin.

In one embodiment of the power die, a high-side device and a low-side device, which are required in DC-DC synchronous power converters, are integrated on the same die. The power die is configured with the switched node (phase node or output) at the bottom of the die.

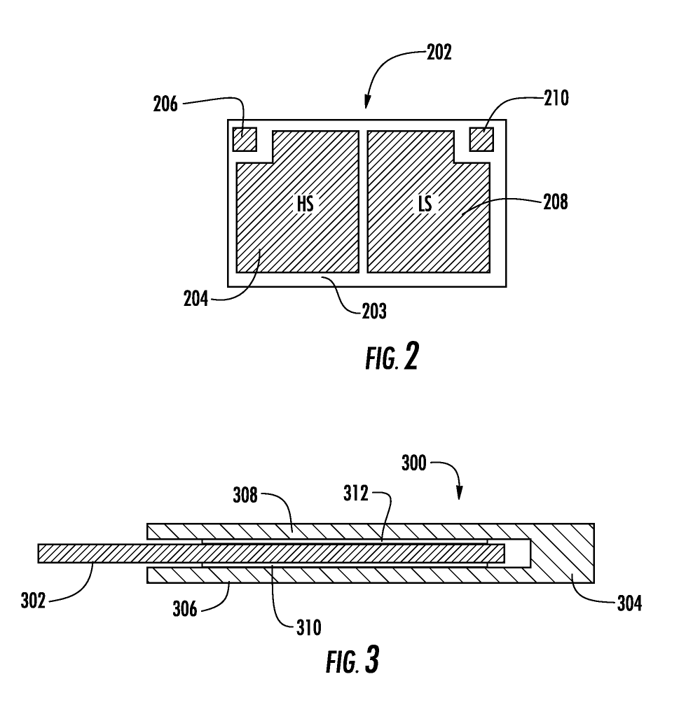

FIG. 2 depicts a power die 202 according to an exemplary embodiment, which can be implemented in the present power converter. The power die 202 includes a high-side (HS) drain pad 204 (Vin) mounted on a substrate 203, and a high-side gate pad 206 mounted adjacent to drain pad 204. A low-side (LS) source pad 208 (ground) is mounted on substrate 203 adjacent to drain pad 204, and a low-side gate pad 210 is mounted adjacent to source pad 208. The high-side drain pad 204 and low-side source pad 208 can be shaped based on the capacitor die connection technique used.

In one embodiment, the capacitor die can be implemented as a textured capacitor such as a trenched capacitor. For example, a trench-gate capacitor can be implemented in the substrate of the stacked capacitor to increase the area. The capacitance per unit area can be increased significantly, without impacting the voltage rating, by using trenched capacitors. In another embodiment, the capacitor die has substantially planar structures. For example, a nitride layer can be deposited on a thin oxide layer to form reliable planar capacitor structures.

FIG. 3 illustrates a capacitor 300 according to one embodiment that can be implemented in the capacitor die. The capacitor 300 includes a first metal electrode 302, and a second metal electrode 304 with extensions 306 and 308. At least a portion of electrode 302 is positioned between electrode extensions 306 and 308. A first dielectric layer 310 is located between electrode 302 and extension 306, and a second dielectric layer 312 is located between electrode 302 and extension 308.

The layers of the capacitor die can be formed by various conventional deposition techniques, such as atomic layer deposition (ALD), low pressure chemical vapor deposition (CVD), metal organic CVD, plasma vapor deposition (PVD) sputtering, and the like.

The dielectric layers of the capacitor die can be formed with various dielectric materials, which can have dielectric constants well in excess of an oxide. For example, a high dielectric constant material, such as barium strontium titanate (BaSrTiO₃), lead zirconium titanate (Pb(ZR₁₋ₓTi)O₃), strontium titanate (SrTiO₃) or tantalum oxide (Ta₂O₅) can be utilized. These materials provide a dielectric constant greater than about 100. Other suitable dielectric materials include hafnium silicate, zirconium silicate, zirconium dioxide, aluminum oxide, and the like.

The foregoing details related to the power die and capacitor are applicable to the additional embodiments of the power converter described as follows.

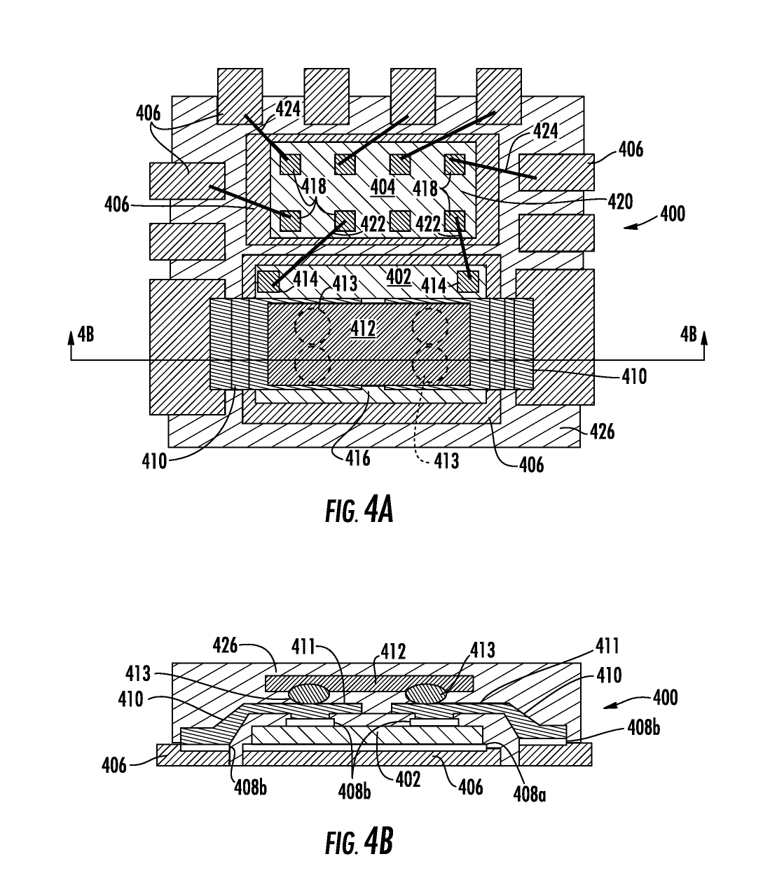

FIGS. 4A and 4B illustrate a power converter 400 according to another embodiment. The power converter 400 includes a power die 402 and an optional IC die 404 that are mounted to inner portions of a metal lead frame 406 with conductive die attach pads 408a. A pair of metal plates 410 is coupled to power die 402 and outer portions of lead frame 406 with a conductive die attach pads 408b. The metal plates 410 each include a raised portion 411 that is coupled to power die 402, and provide one or more conductive paths between power die 402 and lead frame 406.

A capacitor die 412 is mounted on metal plates 410 by flip-chip bonding with one or more solder balls 413. The capacitor die 412 is attached to each raised portion 411 of metal plates 110 over power die 102.

A plurality of bond pads 414 are located on an upper surface 416 of power die 402. A plurality of bond pads 418 are located on an upper surface 420 of IC die 404. The bond pads 414 are electrically connected to respective bond pads 418 by bond wires 422, which provide power signals from power die 402 to IC die 404. Other bond pads 418 are electrically connected to various outer portions of lead frame 406 by bond wires 424 to provide outside connections for IC die 404.

A packaging material 426, such as a polymer molding compound, encapsulates the various components of power converter 400, including power die 402, IC die 404, and capacitor die 412, to seal the components from environmental contamination.

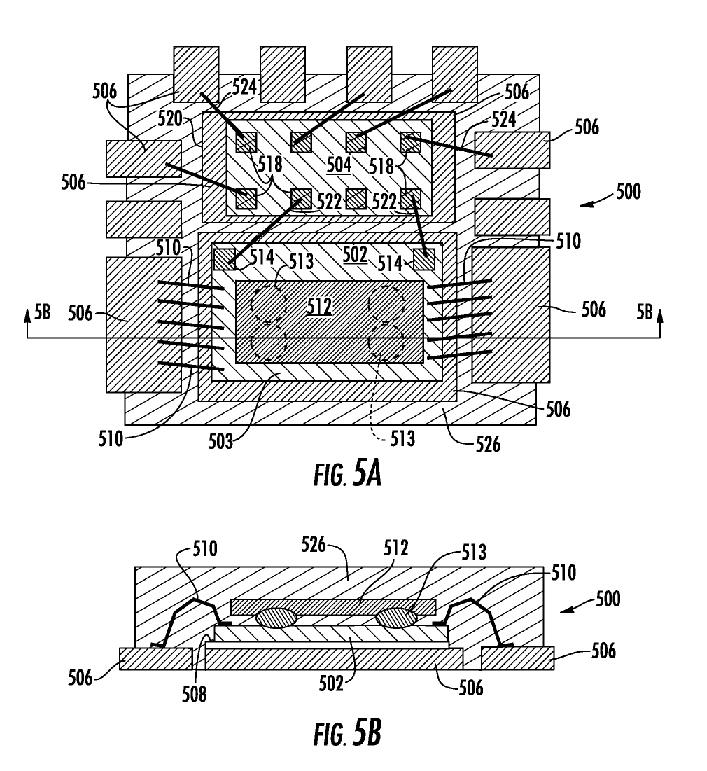

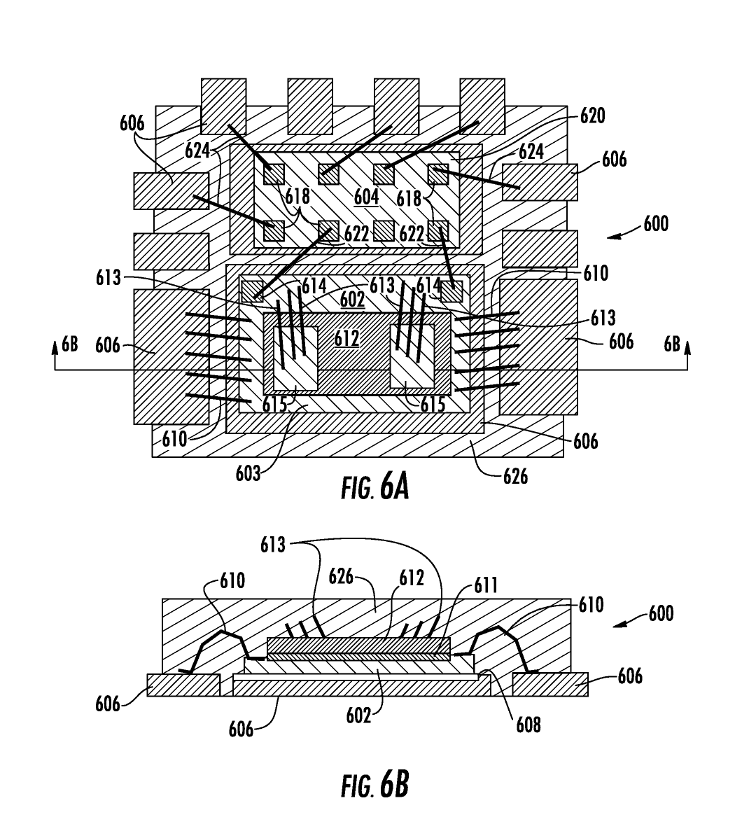

FIGS. 5A and 5B illustrate a power converter 500 according to a further embodiment. The power converter 500 includes a power die 502 and an optional IC die 504 that are mounted to inner portions of a metal lead frame 506 with conductive die attach pads 508. A plurality of bond wires 510 are coupled between an upper surface 503 of power die 502 and outer portions of lead frame 506. The bond wires 510 provide conductive paths between power die 502 and lead frame 506. A capacitor die 512 is mounted on upper surface 503 of power die 502 by flip chip bonding with one or more solder balls 513.

A plurality of bond pads 514 are located on upper surface 503 of power die 502. A plurality of bond pads 518 are located on an upper surface 520 of IC die 504. The bond pads 514 are electrically connected to respective bond pads 518 by bond wires 522, which provide power signals from power die 502 to IC die 504. Other bond pads 518 are electrically connected to various outer portions of lead frame 506 by bond wires 524 to provide outside connections for IC die 504. A packaging material 526 encapsulates the various components of power converter 500, including power die 502, IC die 504, and capacitor die 512.

FIGS. 6A and 6B illustrate a power converter 600 according to another embodiment. The power converter 600 includes a power die 602 and an optional IC die 604 that are mounted to inner portions of a metal lead frame 606 with conductive die attach pads 608. A plurality of bond wires 610 are coupled between an upper surface 603 of power die 602 and outer portions of lead frame 606. The bond wires 610 provide conductive paths between power die 602 and lead frame 606. A capacitor die 612 is mounted on upper surface 603 of power die 602 with an insulating die attach pad 611, which can be an epoxy. A plurality of bond wires 613 attached to a pair of bond pads 615 electrically connect capacitor die 612 to power die 602.

A plurality of bond pads 614 are located on upper surface 603 of power die 602. A plurality of bond pads 618 are located on an upper surface 620 of IC die 604. The bond pads 614 are electrically connected to respective bond pads 618 by bond wires 622, which provide power signals from power die 602 to IC die 604. Other bond pads 618 are electrically connected to various outer portions of lead frame 606 by bond wires 624 to provide outside connections for IC die 604. A packaging material 626 encapsulates the various components of power converter 600, including power die 602, IC die 604, and capacitor die 612.

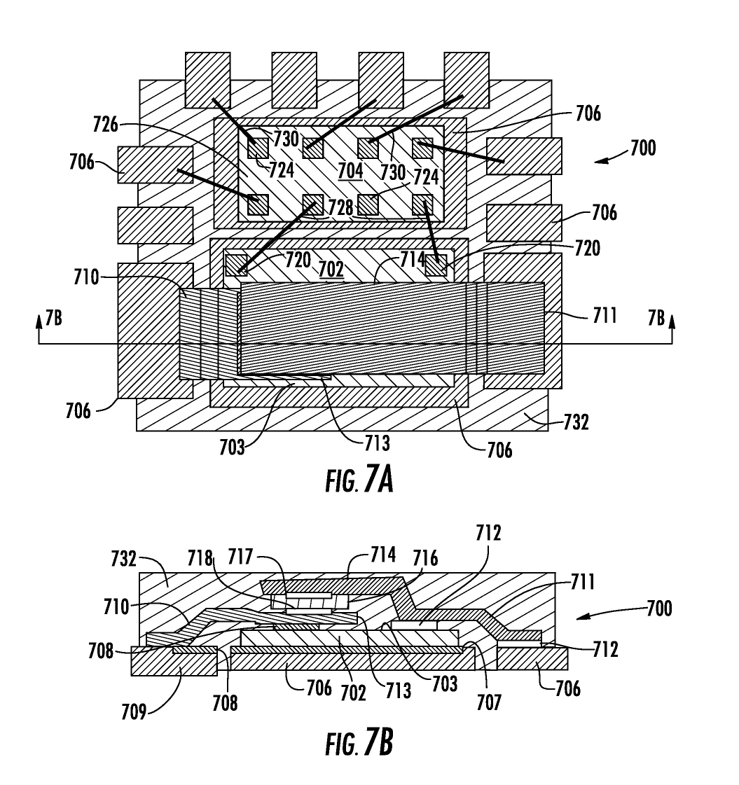

FIGS. 7A and 7B illustrate a power converter 700 according to an additional embodiment. The power converter 700 includes a power die 702 and an optional IC die 704 that are mounted to inner portions of a metal lead frame 706 with conductive die attach pads 707. A first metal plate 710 is coupled to an upper surface 703 of power die 702 and to outer portions of lead frame 706, with conductive die attach pads 708. A second metal plate 711 is coupled to power die 702 and outer portions of lead frame 706 with conductive die attach pads 712. The first metal plate 710 has a raised section 713 that extends over a portion of power die 702. The second metal plate 711 has a raised section 714 that extends over a portion of power die 702 and over a portion of raised section 713.

A capacitor die 716 is mounted between raised section 713 and raised section 714 over power die 702. The capacitor die 716 has a top contact 717 and a bottom contact 718. The top contact 717 is coupled to raised section 714, and bottom contact 718 is coupled to raised section 713.

A plurality of bond pads 720 is located on upper surface 703 of power die 702. A plurality of bond pads 724 is located on an upper surface 726 of IC die 704. The bond pads 720 are electrically connected to respective bond pads 724 by bond wires 728, which provide power signals from power die 702 to IC die 704. Other bond pads 724 are electrically connected to various outer portions of lead frame 706 by bond wires 730 to provide outside connections for IC die 704.

A packaging material 732, such as a polymer molding compound, encapsulates the various components of power converter 700, including power die 702, IC die 704, and capacitor die 716, to seal the components from environmental contamination. A bottom portion 709 of lead frame 706 is exposed through packaging material 732 to the outside environment. The bottom portion 709 provides for electrical connections to the bottom of power die 702, and direct heat sinking to the outside environment.

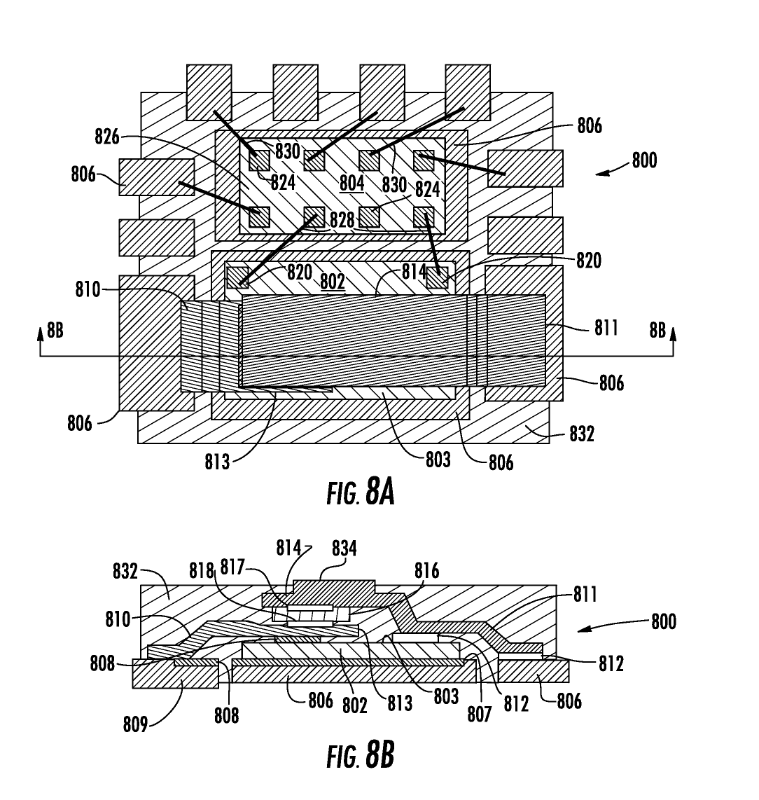

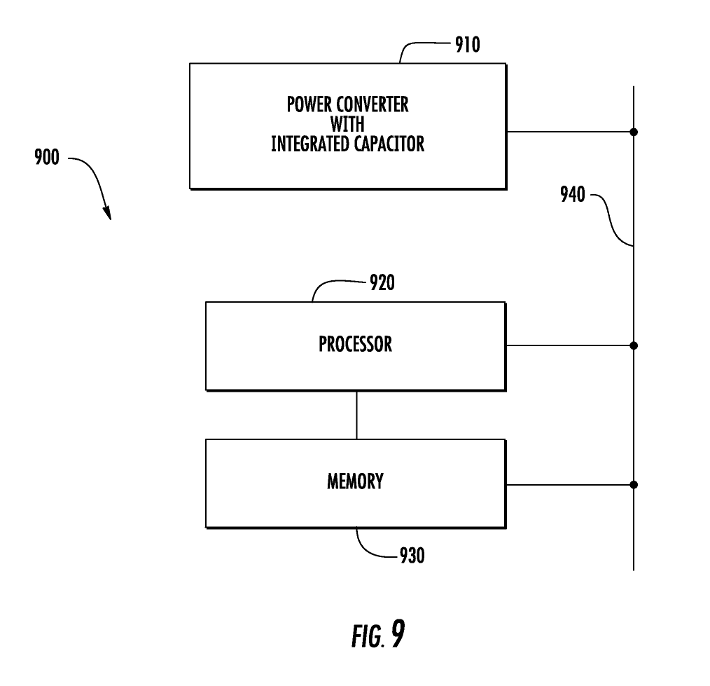

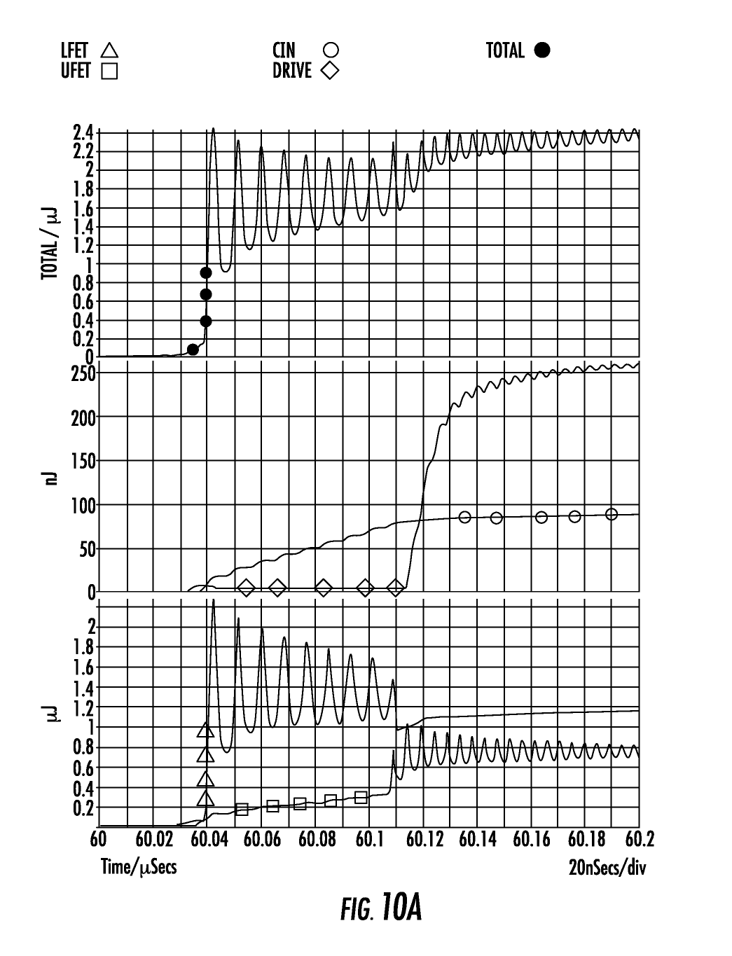

FIGS. 8A and 8B illustrate a power converter 800 according to a further embodiment. The power converter 800 includes a power die 802 and an optional IC die 804 that are mounted to inner portions of a metal lead frame 806 with conductive die attach pads 807. A first metal plate 810 is coupled to an upper surface 803 of power die 802 and to outer portions of lead frame 806, with conductive die attach pads 808.

A second metal plate 811 is coupled to power die 802 and outer portions of lead frame 806 with conductive die attach pads 812. The first metal plate 810 has a raised section 813 that extends over a portion of power die 802. The second metal plate 811 has a raised section 814 that extends over a portion of power die 802 and over a portion of raised section 813.

A capacitor die 816 is mounted between raised section 813 and raised section 814 over power die 802. The capacitor die 816 has a top contact 817 and a bottom contact 818. The top contact 817 is coupled to raised section 814, and bottom contact 818 is coupled to raised section 813.

A plurality of bond pads 820 is located on upper surface 803 of power die 802. A plurality of bond pads 824 is located on an upper surface 826 of IC die 804. The bond pads 820 are electrically connected to respective bond pads 824 by bond wires 828, which provide power signals from power die 802 to IC die 804. Other bond pads 824 are electrically connected to various outer portions of lead frame 806 by bond wires 830 to provide outside connections for IC die 804.

A packaging material 832 encapsulates the various components of power converter 800, including power die 802, IC die 804, and capacitor die 816, to seal the components. A bottom portion 809 of lead frame 806 is exposed through packaging material 832 to the outside environment. The bottom portion 809 provides for electrical connections to the bottom of power die 802, and direct heat sinking to the outside environment.

As shown in FIG. 8B, raised section 814 of metal plate 811 includes a top segment 834 that is exposed through packaging material 832 to the outside environment. The top segment 834 provides direct access to plate 811 for direct heat sinking to the outside environment.

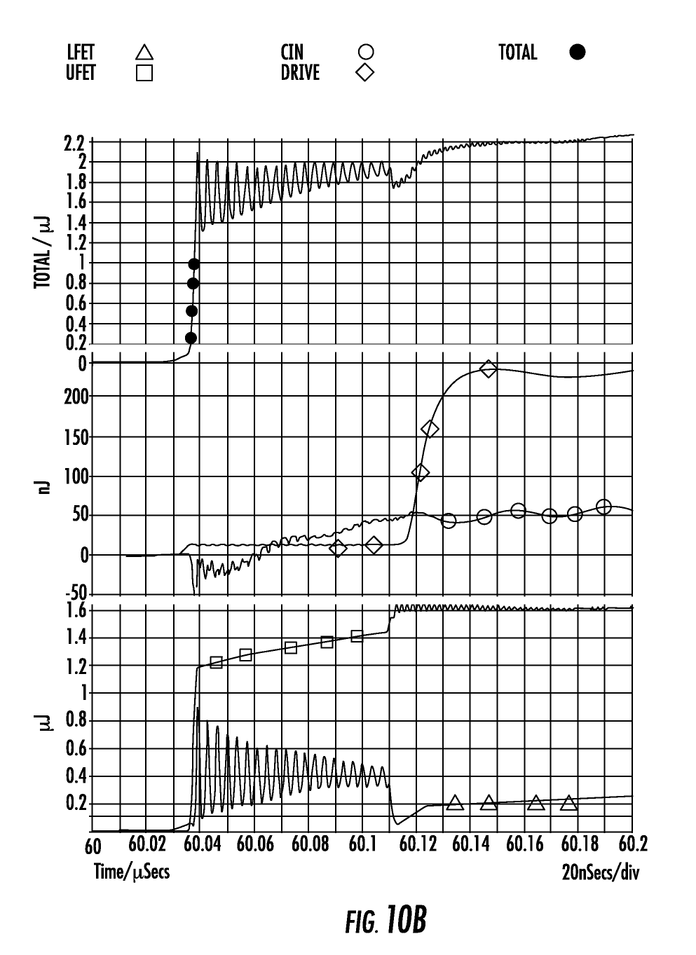

FIG. 9 is a block diagram of an electronic system 900 that includes at least one power converter 910 with one or more integrated capacitors, such as described in the foregoing embodiments. The power converter 910 is electrically coupled to at least one processor 920 and at least one memory unit 930. For example, a bus 940 can provide electrical connections between power converter 910, processor 920, and memory unit 930. The processor 920 and memory unit 930 are also electrically coupled to each other.

### Example 1

The calculated capacitances of various capacitors are set forth in Tables 1 and 2. Table 1 lists the calculated capacitances for capacitors with varying thicknesses of oxide/nitride planar capacitor structures. Table 2 shows that capacitances greater than 1 micro-Farad are feasible when the capacitors are based on dielectric materials with a higher dielectric constant than oxide/nitride. The BV in Table 2 and the BVox in Table 1 are the estimated breakdown voltage of the dielectric or dielectric stack. Typically, the maximum electric field at breakdown is around 9 MeV/cm. The Operating Voltage column in Table 1 is simply ⅓ of the BVox value.

TABLE 1

| | | oxide | | Nitride | | Single Plate | | Operating | Double Plate |
|---|---|---|---|---|---|---|---|---|---|
| Area | Area | Thickness | oxide | Thickness | Nitride | Cap | Estimated | Voltage | Cap |
| mm\hat{ }2 | um\hat{ }2 | (um) | Cap | (um) | Cap | nF | BVox | (1/3) | nF |
| 1 | 1000000 | 0.01 | 3.45313E−09 | 0.02 | 3.32032E−09 | 1.69 | 18 | 6 | 3.39 |
| 2 | 2000000 | 0.01 | 6.90626E−09 | 0.02 | 6.64064E−09 | 3.39 | 18 | 6 | 6.77 |
| 5 | 5000000 | 0.01 | 1.72657E−08 | 0.02 | 1.66016E−08 | 8.46 | 18 | 6 | 16.93 |
| 8 | 8000000 | 0.01 | 2.7625E−08 | 0.02 | 2.65625E−08 | 13.54 | 18 | 6 | 27.08 |
| 10 | 10000000 | 0.01 | 3.45313E−08 | 0.02 | 3.32032E−08 | 16.93 | 18 | 6 | 33.85 |
| 20 | 20000000 | 0.01 | 6.90526E−08 | 0.02 | 6.64064E−08 | 33.85 | 18 | 6 | 67.71 |
| 1 | 1000000 | 0.01 | 3.45313E−09 | 0.04 | 1.66016E−09 | 1.12 | 36 | 12 | 2.24 |
| 2 | 2000000 | 0.01 | 6.90626E−09 | 0.04 | 3.32032E−09 | 2.24 | 36 | 12 | 4.48 |
| 5 | 5000000 | 0.01 | 1.72657E−08 | 0.04 | 8.30079E−09 | 5.61 | 36 | 12 | 11.21 |
| 8 | 8000000 | 0.01 | 2.7625E−08 | 0.04 | 1.32813E−08 | 8.97 | 36 | 12 | 17.94 |
| 10 | 10000000 | 0.01 | 3.45313E−08 | 0.04 | 1.66016E−08 | 11.21 | 36 | 12 | 22.42 |
| 20 | 20000000 | 0.01 | 6.90626E−08 | 0.04 | 3.32032E−08 | 22.42 | 36 | 12 | 44.85 |
| 1 | 1000000 | 0.01 | 3.45313E−09 | 0.08 | 8.30079E−10 | 0.67 | 72 | 24 | 1.34 |
| 2 | 2000000 | 0.01 | 6.90626E−09 | 0.08 | 1.66016E−09 | 1.34 | 72 | 24 | 2.68 |
| 5 | 5000000 | 0.01 | 1.72657E−08 | 0.08 | 4.1504E−09 | 3.35 | 72 | 24 | 6.69 |
| 8 | 8000000 | 0.01 | 2.7625E−08 | 0.08 | 6.64064E−09 | 5.35 | 72 | 24 | 10.71 |
| 10 | 10000000 | 0.01 | 3.45313E−08 | 0.08 | 8.30079E−09 | 6.69 | 72 | 24 | 13.38 |
| 20 | 20000000 | 0.01 | 6.90626E−08 | 0.08 | 1.66016E−08 | 13.38 | 72 | 24 | 26.77 |

TABLE 2

| | | | | Single | Double | Single | Double | Single | Double |
|---|---|---|---|---|---|---|---|---|---|
| | | | | Plate | Plate | Plate | Plate | Plate | Plate |
| | | | Dielectric | Die. Const. | Die. Const. | Die. Const. | Die. Const. | Die. Const. | Die. Const. |
| Area | Area | BV | Thickness | 10 | 10 | 20 | 20 | 100 | 100 |
| mm\hat{ }2 | um\hat{ }2 | V | (um) | nF | nF | nF | nF | nF | nF |
| 1 | 1000000 | 18 | 0.02 | 4.43 | 8.85 | 8.85 | 17.71 | 44.27 | 88.54 |
| 2 | 2000000 | 18 | 0.02 | 8.85 | 17.71 | 17.71 | 35.42 | 88.54 | 177.08 |
| 5 | 5000000 | 18 | 0.02 | 22.14 | 44.27 | 44.27 | 88.54 | 221.35 | 442.71 |
| 8 | 8000000 | 18 | 0.02 | 35.42 | 70.83 | 70.83 | 141.67 | 354.17 | 708.33 |
| 10 | 10000000 | 18 | 0.02 | 44.27 | 88.54 | 88.54 | 177.08 | 442.71 | 885.42 |
| 15 | 15000000 | 18 | 0.02 | 66.41 | 132.81 | 132.81 | 265.63 | 664.06 | 1328.13 |
| 20 | 20000000 | 18 | 0.02 | 88.54 | 177.08 | 177.08 | 354.17 | 885.42 | 1770.84 |
| 1 | 1000000 | 36 | 0.04 | 2.21 | 4.43 | 4.43 | 8.85 | 22.14 | 44.27 |
| 2 | 2000000 | 36 | 0.04 | 4.43 | 8.85 | 8.85 | 17.71 | 44.27 | 88.54 |
| 5 | 5000000 | 36 | 0.04 | 11.07 | 22.14 | 22.14 | 44.27 | 110.68 | 221.35 |
| 8 | 8000000 | 36 | 0.04 | 17.71 | 35.42 | 35.42 | 70.83 | 177.08 | 354.17 |
| 10 | 10000000 | 36 | 0.04 | 22.14 | 44.27 | 44.27 | 88.54 | 221.35 | 442.71 |
| 15 | 15000000 | 36 | 0.04 | 33.20 | 66.41 | 66.41 | 132.81 | 332.03 | 664.06 |
| 20 | 20000000 | 36 | 0.04 | 44.27 | 88.54 | 88.54 | 177.08 | 442.71 | 885.42 |
| 1 | 1000000 | 72 | 0.08 | 1.11 | 2.21 | 2.21 | 4.43 | 11.07 | 22.14 |
| 2 | 2000000 | 72 | 0.08 | 2.21 | 4.43 | 4.43 | 8.85 | 22.14 | 44.27 |
| 5 | 5000000 | 72 | 0.08 | 5.53 | 11.07 | 11.07 | 22.14 | 55.34 | 110.68 |
| 8 | 8000000 | 72 | 0.08 | 8.85 | 17.71 | 17.71 | 35.42 | 88.54 | 177.08 |
| 10 | 10000000 | 72 | 0.08 | 11.07 | 22.14 | 22.14 | 44.27 | 110.68 | 221.35 |
| 15 | 15000000 | 72 | 0.08 | 16.60 | 33.20 | 33.20 | 66.41 | 166.02 | 332.03 |
| 20 | 20000000 | 72 | 0.08 | 22.14 | 44.27 | 44.27 | 88.54 | 221.35 | 442.71 |

### Example 2

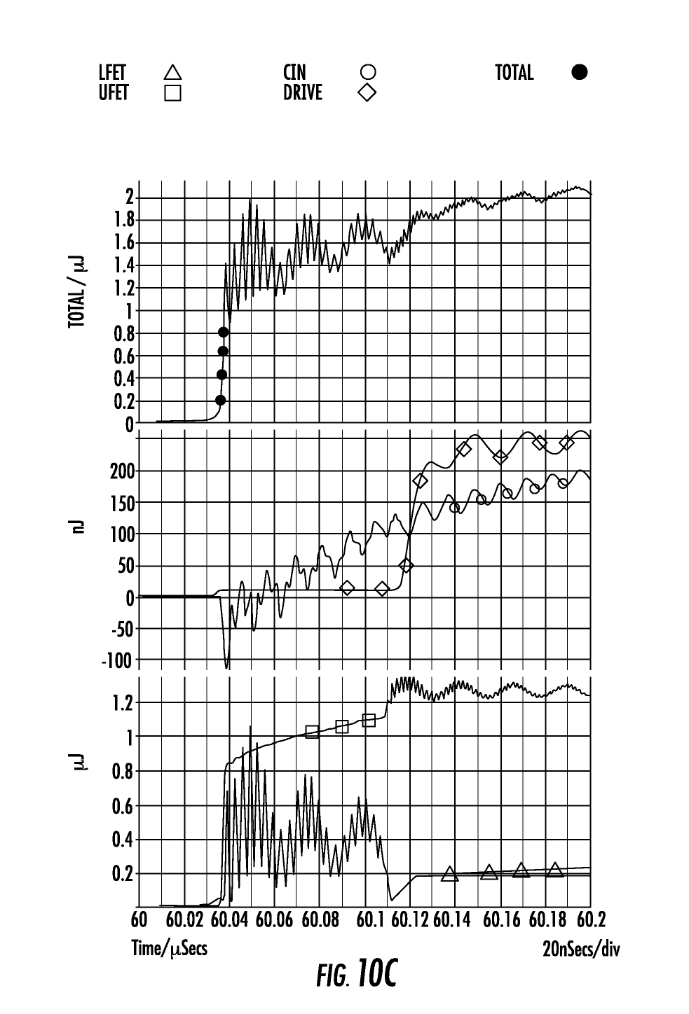

Computer simulations using published transistor models were carried out in order to evaluate the impact of an integrated capacitor on circuit performance. The results of the simulations are shown in the graphs of FIGS. 10A-10C. The results in FIGS. 10A-10C show power loss (vertical axis) versus time (horizontal axis), in which in which lower values indicate higher efficiency. The various plots in the graphs represent LFET (Low-Side or lower field effect transistor (FET)), UFET (High-Side or upper FET), CIN (input capacitor) and DRIVE (related to the input power), and the TOTAL power loss.

FIG. 10A shows the results without the use of any capacitor, in which the total power loss was 2.4 μJ. FIG. 10B shows the results of using a 100 nF capacitor, in which the total power loss was 2.2 μJ. FIG. 10C shows the results of using a 10 nF capacitor in which the total power loss was 2.0 μJ. The results in FIG. 10C confirm that fine tuning the capacitance can yield improved performance as more capacitance is not necessarily lower power loss.

The computer simulations showed that adding capacitance reduces total power loss by about 10% and also reduces ringing. Also, by fine tuning the capacitance for the application (depending on inductance, etc.), up to about 20% reduction in power loss can be achieved.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A power converter device, comprising:
a substrate;
a power die mounted on the substrate;
a capacitor die mounted over the power die in a stacked configuration, the capacitor die electrically coupled to the power die; and
a packaging material encapsulating the power die and the capacitor die.

2. The power converter device of claim 1, wherein the substrate comprises a metal lead frame having an inner portion and an outer portion.

3. The power converter device of claim 2, wherein the power die is mounted on the inner portion of the metal lead frame.

4. The power converter device of claim 2, further comprising a pair of metal plates conductively coupled to the power die and the outer portion of the lead frame such that the metal plates provide one or more conductive paths between the power die and the outer portion of the lead frame.

5. The power converter device of claim 4, wherein the capacitor die is mounted on the metal plates over the power die.

6. The power converter device of claim 5, wherein the capacitor die is mounted on the metal plates by flip-chip bonding with one or more conductive die attach pads or one or more solder balls.

7. The power converter device of claim 2, further comprising a first plurality of bond wires coupled between an upper surface of the power die and the outer portion of the lead frame, the first plurality of bond wires providing a conductive path between the power die and the lead frame.

8. The power converter device of claim 7, wherein the capacitor die is mounted on the power die by flip-chip bonding with one or more solder balls.

9. The power converter device of claim 7, wherein the capacitor die is mounted on the power die with an insulating die attach pad, and the capacitor die is electrically connected to the power die with a second plurality of bond wires.

10. The power converter device of claim 2, further comprising:
a first metal plate conductively coupled to the power die and the outer portion of the lead frame, the first metal plate having a raised section that extends over a portion of the power die; and
a second metal plate conductively coupled to the power die and the outer portion of the lead frame, the second metal plate having a raised section that extends over a portion of the power die and over a portion of the raised section of the first metal plate.

11. The power converter device of claim 10, wherein the capacitor die is mounted between the raised sections of the first and second metal plates over the power die.

12. The power converter device of claim 11, wherein the capacitor die comprises a top contact coupled to the raised section of the second metal plate, and a bottom contact coupled to the raised section of the first metal plate.

13. The power converter device of claim 10, wherein a bottom portion of the lead frame is exposed through the packaging material.

14. The power converter device of claim 13, wherein the raised section of the second metal plate includes a top segment that is exposed through the packaging material.

15. The power converter device of claim 1, wherein the power die comprises:
a substrate;
a high-side drain pad coupled to the substrate, a high-side gate pad coupled to the substrate adjacent to the high-side drain pad;
a low-side source pad coupled to the substrate adjacent to the high-side drain pad; and
a low-side gate pad coupled to the substrate adjacent to the low-side source pad.

16. The power converter device of claim 1, wherein the capacitor die comprises:
a first metal electrode;
a second metal electrode with a first extension and a second extension that at least partially surround the first metal electrode;
a first dielectric layer located between the first metal electrode and the first extension; and
a second dielectric layer located between the first metal electrode and the second extension.

17. The power converter device of claim 1, wherein the capacitor die includes one or more dielectric layers comprising barium strontium titanate, lead zirconium titanate, strontium titanate, tantalum oxide, hafnium silicate, zirconium silicate, zirconium dioxide, or aluminum oxide.

18. A power converter device, comprising:
a substrate comprising a metal lead frame having an inner portion and an outer portion;
a power die mounted on the inner portion of the lead frame;
a capacitor die mounted over the power die in a stacked configuration, the capacitor die electrically coupled to the power die;
an integrated circuit die mounted to the substrate and electrically coupled to the outer portion of the lead frame; and
a packaging material encapsulating the power die and the capacitor die;
wherein the integrated circuit die is electrically coupled to the power die to receive power signals from the power die.

19. The power converter device of claim 18, further comprising a pair of metal plates conductively coupled to the power die and the outer portion of the lead frame such that the metal plates provide one or more conductive paths between the power die and the outer portion of the lead frame.

20. The power converter device of claim 19, wherein the capacitor die is mounted on the metal plates by flip-chip bonding with one or more conductive die attach pads or one or more solder balls.

21. The power converter device of claim 18, further comprising a first plurality of bond wires coupled between an upper surface of the power die and the outer portion of the lead frame, the first plurality of bond wires providing a conductive path between the power die and the lead frame.

22. The power converter device of claim 21, wherein the capacitor die is mounted on the power die by flip-chip bonding with one or more solder balls.

23. The power converter device of claim 21, wherein the capacitor die is mounted on the power die with an insulating die attach pad, and the capacitor die is electrically connected to the power die with a second plurality of bond wires.

24. The power converter device of claim 18, further comprising:
a first metal plate conductively coupled to the power die and the outer portion of the lead frame, the first metal plate having a raised section that extends over a portion of the power die; and
a second metal plate conductively coupled to the power die and the outer portion of the lead frame, the second metal plate having a raised section that extends over a portion of the power die and over a portion of the raised section of the first metal plate.

25. The power converter device of claim 24, wherein the capacitor die is mounted between the raised sections of the first and second metal plates over the power die.

26. The power converter device of claim 24, wherein a bottom portion of the lead frame is exposed through the packaging material.

27. The power converter device of claim 26, wherein the raised section of the second metal plate includes a top segment that is exposed through the packaging material.

28. An electronic system comprising:
at least one processor:
at least on memory unit operatively coupled to the processor; and
at least one power converter electrically coupled to the processor and the memory unit, the power converter comprising:
a metal lead frame having an inner portion and an outer portion;
a power die mounted on the inner portion of the lead frame;
a capacitor die mounted over the power die in a stacked configuration, the capacitor die electrically coupled to the power die; and
a packaging material encapsulating the power die and the capacitor die.

29. The electronic system of claim 28, further comprising an integrated circuit die mounted to the lead frame, the integrated circuit electrically coupled to the power die and the outer portion of the lead frame.

30. A method of manufacturing a power converter device, comprising:
providing a substrate;
mounting a power die on the substrate;
mounting a capacitor die over the power die in a stacked configuration;
electrically coupling the capacitor die to the power die; and
encapsulating the power die and the capacitor die with a packaging material.

31. The method of claim 30, further comprising:
mounting an integrated circuit die on the substrate; and
electrically coupling the integrated circuit die to the power die.
